(19) United States
(12) Patent Application Publication
(10) Pub. No.: US 2007/0188274 A1
(43) Pub. Date: Aug. 16, 2007

(54) ACTIVE INDUCTOR

(75) Inventor: Kazuo Kawai, Tokyo (JP)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: GENERAL RESEARCH OF ELECTRONICS, INC., Tokyo (JP)

(21) Appl. No.: 11/674,281

(22) Filed: Feb. 13, 2007

(30) Foreign Application Priority Data
Feb. 16, 2006 (JP) 2006-39468

(51) Int. Cl. H03H 11/48

(52) U.S. Cl. 333/214

(57) ABSTRACT

The present invention provides an active inductor that includes an active all-pass type 90° phase advancing circuit comprising an operational amplifier, a first resistor connected between an inversion input end of the operational amplifier and an input terminal, a capacitor connected between a non-inversion input end of the operational amplifier and the input terminal, a second resistor connected between an output end of the operational amplifier and the non-inversion input end, and a third resistor connected between the non-inversion input end and a ground point; and a fourth resistor having a resistance value sufficiently lower than respective resistance values of the first through third resistors connected between input and output terminals of the active all-pass type 90° phase advancing circuit and an impedance value of the capacitor. Thus, an equivalent inductor is obtained between the input terminal and the ground point.

### RELATED/PRIORITY APPLICATION

This application claims priority with respect to Japanese Application No. 2006-39468, filed Feb. 16, 2006.

### BACKGROUND OF THE INVENTION

1. Field of the Invention

The present invention relates to an active inductor, and particularly to an active inductor wherein the magnitude of a drive current supplied between input terminals is changed using one operational amplifier, a plurality of resistive elements and one reactive element, thereby making it possible to obtain a variable inductance value between the input terminals.

2. Description of the Related Art

In general, a lumped constant type filter needs to change the capacitance value of a capacitor used therein and the inductance value of an inductor used therein when a cut-off frequency of the lumped constant type filter and a bandwidth or the like thereof are changed. Further, when the cut-off frequency and the bandwidth are continuously changed, it is necessary to configure the lumped constant type filter in such a manner that the capacitance value of the capacitor and the inductance value of the inductor can be changed within their corresponding prescribed ranges.

When the capacitance value of the capacitor is changed where the cut-off frequency and bandwidth of the lumped constant type filter are continuously changed, a relatively high-capacity variable capacitance diode is used, thereby making it possible to easily set its capacitance value to a necessary value. When, however, the inductance value of the inductor is changed, there no exists an element indicative of such a characteristic in single form. Therefore, a generalized impedance converter (GIC) is normally used.

The generalized impedance converter (GIC) is configured by a combination of two operational amplifiers and series-connected five impedance elements Z1, Z2, Z3, Z4 and Z5. Assuming that, for example, the impedance element Z4 is configured as a capacitor and all the other impedance elements Z1, Z2, Z3 and Z5 are respectively configured as resistors using that an input impedance Z of the generalized impedance converter (GIC) comes to Z=Z1·Z3·Z5/(Z2·Z4), the generalized impedance converter is brought to an active inductor in which the input impedance Z becomes an inductance value. If the resistance values of any one or more of the resistors constituted of the impedance elements Z1, Z2, Z3 and Z5 are changed, then the magnitude of the inductance value of the active inductor can be changed.

The lumped constant type filter using such a generalized impedance converter needs not to connect and lay out a plurality of inductors within the lumped constant type filter and dispose an inductor connection switching means for selecting one or more out of the plurality of inductors. It is enough if the lumped constant type filter is configured so as to be capable of changing the resistance values of one or more resistors lying within the generalized impedance converter. It is thus possible to simplify a circuit configuration of the lumped constant type filter.

Since there is used, as the generalized impedance converter, one using the combination of the two operational amplifiers and the series-connected five impedance elements Z1, Z2, Z3, Z4 and Z5 although the lumped constant type filter using the generalized impedance converter can be simplified in circuit configuration, the simplification of its circuit configuration is insufficient. Hence, there has been a demand for appearance of an impedance converter more simplified in circuit configuration.

### SUMMARY OF THE INVENTION

The present invention has been made in view of such a technical background. It is therefore an object of the present invention to provide an active inductor capable of remarkably simplifying a circuit configuration by using an active all-pass type 90° phase advancing circuit comprising a signal operational amplifier, a plurality of resistors and a single reactive element and changing an inductance value of the active inductor by adjusting a resistance value of one resistor.

In order to attain the above object, there is provided an active inductor according to the present invention, which includes first constituting means comprising:

input terminals;

an active all-pass type 90° phase advancing circuit comprising an operational amplifier, a first resistor connected between an inversion input end of the operational amplifier and the corresponding input terminal, a capacitor connected between a non-inversion input end of the operational amplifier and the input terminal, a second resistor connected between an output end of the operational amplifier and the inversion input end, and a third resistor connected between the non-inversion input end of the operational amplifier and a ground point; and

a fourth resistor having a resistance value sufficiently lower than respective resistance values of the first through third resistors connected between input and output terminals of the active all-pass type 90° phase advancing circuit and an impedance value of the capacitor,

whereby an equivalent inductor is obtained between the input terminal and the ground point.

In order to attain the above object, there is provided an active inductor according to the present invention, which includes second constituting means comprising:

input terminals;

an active all-pass type 90° phase advancing circuit comprising an operational amplifier, a first resistor connected between an inversion input end of the operational amplifier and the corresponding input terminal, a second resistor connected between a non-inversion input end of the operational amplifier and the input terminal, a third resistor connected between an output end of the operational amplifier and the inversion input end, and an inductor connected between the non-inversion input end of the operational amplifier and a ground point; and

a fourth resistor having a resistance value sufficiently lower than respective resistance values of the first through third resistors connected between input and output terminals of the active all-pass type 90° phase advancing circuit and an impedance value of the inductor,

whereby an equivalent inductor is obtained between the input terminal and the ground point.

The first constituting means and the second constituting means are respectively obtained based on the following principle of constitution. That is, an inductor is one wherein the phase of a flowing current leads by 90° the phase of a voltage applied thereto. A circuit that assumes the same phase state as these phase states is configured using an operational amplifier, a capacitor and a resistor or configured using an operational amplifier, an inductor and a resistor. Such a circuit may be set to such a configuration that after the formation of an active all-pass type 90° phase advancing circuit for allowing an input signal to be phase-advanced by 90°, a current that flows from an input terminal to the active all-pass type 90° phase advancing circuit is controlled using a signal outputted from the active all-pass type 90° phase advancing circuit. Thus, an active inductor can be obtained between input terminals.

According to an active inductor of the present invention as described above in detail, it is configured using an active all-pass type 90° phase advancing circuit constituted of a single operational amplifier, a plurality of resistors and a single reactive element, and a resistor having a small resistance value, which is connected between an input and output of the active all-pass type 90° phase advancing circuit. Therefore, the active inductor brings about advantageous effects in that it can not only simplify its circuit configuration remarkably but also obtain an extensively changed inductance value by adjusting the resistance value of one of the plurality of resistors.

Other features and advantages of the present invention will become apparent upon a reading of the attached specification.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein like reference numerals identify like elements in which:

FIG. 1 shows a first embodiment of an active inductor according to the present invention and is a circuit diagram showing a circuit configuration thereof; and

FIG. 2 shows a second embodiment of an active inductor according to the present invention and is a circuit diagram showing a circuit configuration thereof.

### DETAILED DESCRIPTION OF THE PREFERRED EMBODIMENTS

Preferred embodiments of the present invention will be described hereinafter with reference to the accompanying drawings.

### First Preferred Embodiment

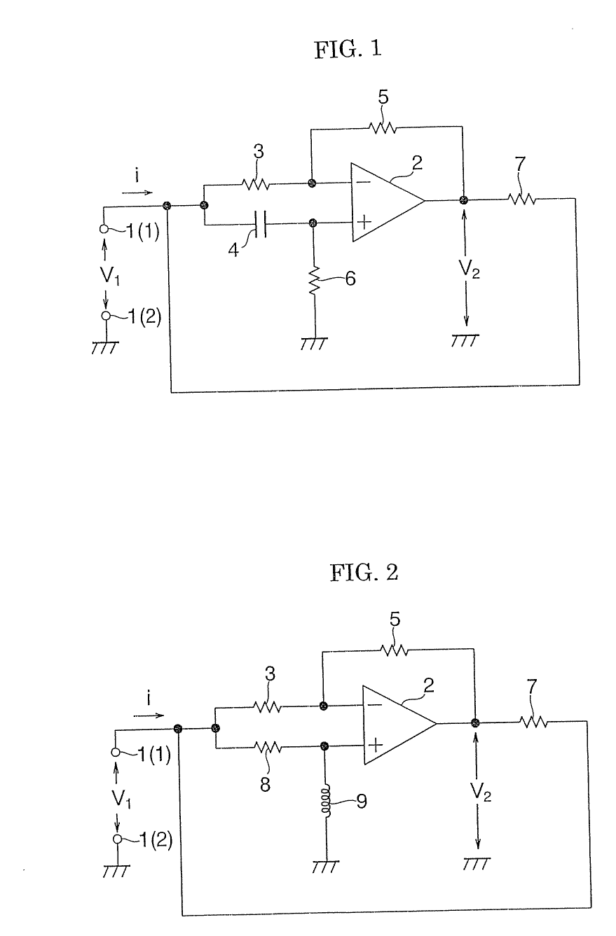

FIG. 1 shows a first embodiment of an active inductor according to the present invention and is a circuit diagram showing a circuit configuration thereof.

As shown in FIG. 1, the active inductor according to the first embodiment comprises input terminals 1(1) and 1(2), an operational amplifier 2, a first resistor 3, a capacitor 4, a second resistor 5, a third resistor 6 and a fourth resistor 7. The operational amplifier 2 has an inversion input end (−) connected with the first resistor 3 which is connected between the inversion input end (−) thereof and the input terminal 1(1), a non-inversion input end (+) connected with the capacitor 4 which is connected between the non-inversion input end (+) thereof and the input terminal 1(1), and an output end connected with the second resistor 5 which is connected between the output end thereof and the inversion input end (−). The third resistor 6 is connected between the non-inversion input end (+) of the operational amplifier 2 and a ground point. The fourth resistor 7 is connected between the output end of the operational amplifier 2 and the input terminal 1(1). In this case, a circuit section comprising the operational amplifier 2, the first resistor 3, the capacitor 4, the second resistor 5 and the third resistor 6 constitutes an active all-pass type 90° phase advancing circuit that allows signals lying in all used frequency bands to pass therethrough.

When a resistance value R₁ of the first resistor 3 and a resistance value R₂ of the second resistor 5 are selected equally (R₁=R₂) assuming that under the above configuration, a drive voltage applied between the input terminals 1(1) and 1(2) is V₁, an output voltage developed at the output end of the operational amplifier 2 is V₂, the resistance value of the first resistor 3 is R₁, the capacitance value of the capacitor 4 is C₀, the resistance value of the second resistor 5 is R₂, the resistance value of the third resistor 6 is R₀ and the resistance value of the fourth resistor 7 is r, the following equation (1) is established at the active inductor according to the above configuration.

That is, a transfer function V₂/V₁ at the active all-pass type 90° phase advancing circuit is expressed as indicated by the following equation (1) if s is assumed to be a Laplace transformer:

$$\frac{{V}_{2}}{{V}_{1}} = \frac{s - \frac{1}{{C}_{0} {R}_{0}}}{s + \frac{1}{{C}_{0} {R}_{0}}} \qquad ( 1 )$$

The active all-pass type 90° phase advancing circuit used herein has all-pass characteristics with respect to all used frequencies as indicated by the equation (1). It performs a phase shift of exactly +90° at a frequency ω=1/C₀R₀.

Assuming that the resistance value r of the fourth resistor 7 is set to a resistance value considerably smaller than the resistance value R₁ of the first resistor 3, the resistance value R₂ of the second resistor 5, the resistance value R₀ of the third resistor 6 and the capacitance value 1/sC₀ of the capacitor 4 in the active inductor according to the first embodiment, a current i based on the drive voltage V₁ applied between the input terminals 1(1) and 1(2) practically flows through the fourth resistor 7 having the resistance value r. The current i is expressed in the following equation (2):

$$i = \frac{{V}_{1} - {V}_{2}}{r} \qquad ( 2 )$$

If an input impedance V₁/i of the active inductor according to the first embodiment is determined from these equations (1) and (2), it is then given as expressed in the following equation (3):

$$\frac{{V}_{1}}{i} = \frac{r}{2} + s \frac{{C}_{0} {R}_{0} r}{2} \qquad ( 3 )$$

Thus, if the active inductor according to the first embodiment is expressed as an equivalent inductance L₁ using the resistance value R₀ of the third resistor 6, the capacitance value C₀ of the capacitor 4 and the resistance value r of the fourth resistor 7, it then becomes L₁=C₀R₀r/2. A resistance component at this time results in r/2. Now consider the following as one example of the active inductor. That is, when the capacitance value C₀ of the capacitor 4 is assumed to be 0.1 μF, the resistance value R₀ of the third resistor 6 is assumed to be 100 kΩ and the resistance value r of the fourth resistor 7 is assumed to be 2 Ω respectively, 10 mH can be obtained as the equivalent inductance L₁. If the resistance value R₀ of the third resistor 6 is changed from 1 kΩ to 500 kΩ, then the equivalent inductance L₁ can be continuously changed from 100 nH to 50 mH. Thus, the equivalent inductance L₁ becomes a value proportional to the resistance value R₀ of the third resistor 6.

### Second Preferred Embodiment

Next, FIG. 2 shows a second embodiment of an active inductor according to the present invention and is a circuit diagram showing a circuit configuration thereof.

As shown in FIG. 2, the active inductor according to the second embodiment comprises input terminals 1(1) and 1(2), an operational amplifier 2, a first resistor 3, a second resistor 5, a fourth resistor 7, a fifth resistor 8 (corresponding to a second resistor as defined in claim 2) and an inductor 9. The operational amplifier 2 has an inversion input end (−) connected with the first resistor 3 which is connected between the inversion input end (−) thereof and the input terminal 1(1), a non-inversion input end (+) connected with the fifth resistor 8 which is connected between the non-inversion input end (+) thereof and the input terminal 1(1), and an output end connected with the second resistor 5 which is connected between the output end of the operational amplifier 2 and the inversion input end (−) thereof. The inductor 9 is connected between the non-inversion input end (+) and a ground point. The fourth resistor 7 is connected between the output end of the operational amplifier 2 and the input terminal 1(1) thereof. Even in this case, a circuit section comprising the operational amplifier 2, the first resistor 3, the fifth resistor 8, the second resistor 5 and the inductor 9 constitutes an active all-pass type 90° phase advancing circuit that allows signals lying in all used frequency bands to pass therethrough.

When a resistance value R₁ of the first resistor 3 and a resistance value R₂ of the second resistor 5 are selected equally (R₁=R₂) assuming that under the above configuration, a drive voltage applied between the input terminals 1(1) and 1(2) is V₁, an output voltage developed at the output end of the operational amplifier 2 is V₂, the resistance value of the first resistor 3 is R₁, the resistance value of the second resistor 5 is R₂, the resistance value of the fifth resistor 8 is R₀, the inductance value of the inductor 9 is L₀ and the resistance value of the fourth resistor 7 is r, the following equation (4) is established at the active inductor according to the above configuration.

That is, a transfer function V₂/V₁ at the active all-pass type 90° phase advancing circuit is expressed as indicated by the following equation (4) if s is assumed to be a Laplace transformer:

$$\frac{{V}_{2}}{{V}_{1}} = \frac{s - \frac{{R}_{0}}{{L}_{0}}}{s + \frac{{R}_{0}}{{L}_{0}}} \qquad ( 4 )$$

Even in this case, the active all-pass type 90° phase advancing circuit has all-pass characteristics with respect to all used frequencies as indicated by the equation (4). It performs a phase shift of exactly +90° at a frequency ω=R₀/L₀.

Assuming that the resistance value r of the fourth resistor 7 is set to a resistance value considerably smaller than the resistance value R₁ of the first resistor 3, the resistance value R₂ of the second resistor 5, the resistance value R₀ of the fifth resistor 8 and the inductance value sL₀ of the inductor 9 even in the active inductor according to the second embodiment, a current i based on the drive voltage V₁ applied between the input terminals 1(1) and 1(2) practically flows through the fourth resistor 7 having the resistance value r. The current i is expressed in the previous equation (2).

If an input impedance V₁/i of the active inductor according to the second embodiment is determined from these equations (4) and (2), it is then given as expressed in the following equation (5):

$$\frac{{V}_{1}}{i} = \frac{r}{2} + s \frac{{L}_{0} r}{2 {R}_{0}} \qquad ( 5 )$$

Thus, if the active inductor according to the second embodiment is expressed as an equivalent inductance L₂ using the resistance value R₀ of the fifth resistor 8, the inductance value L₀ of the inductor 9 and the resistance value r of the fourth resistor 7, then the active inductor becomes L₂=L₀r/2R₀. The equivalent inductance L₂ becomes a value inversely proportional to the resistance value R₀ of the third resistor 6. In the second embodiment, there is a need to set the inductance value of the inductor 9 to 1H even though the resistance value R₀ of the fifth resistor 8 is set to 100 Ω, in order to obtain 10 mH as the equivalent inductance L₂ assuming that the resistance value r of the four resistor 7 is 2 Ω. Therefore, it is advantageous to use the active inductor according to the first embodiment as compared with the active inductor according to the second embodiment.

While the preferred forms of the present invention have been described, it is to be understood that modifications will be apparent to those skilled in the art without departing from the spirit of the invention. The scope of the invention is to be determined solely by the following claims.

What is claimed is:

1. An active inductor comprising:
input terminals;
an active all-pass type 90° phase advancing circuit comprising an operational amplifier, a first resistor connected between an inversion input end of the operational amplifier and the corresponding input terminal, a capacitor connected between a non-inversion input end of the operational amplifier and the input terminal, a second resistor connected between an output end of the operational amplifier and the inversion input end, and a third resistor connected between the non-inversion input end of the operational amplifier and a ground point; and
a fourth resistor having a resistance value sufficiently lower than respective resistance values of the first through third resistors connected between input and output terminals of the active all-pass type 90° phase advancing circuit and an impedance value of the capacitor,
whereby an equivalent inductor is obtained between the input terminal and the ground point.

2. An active inductor comprising:
input terminals;
an active all-pass type 90° phase advancing circuit comprising an operational amplifier, a first resistor connected between an inversion input end of the operational amplifier and the corresponding input terminal, a second resistor connected between a non-inversion input end of the operational amplifier and the input terminal, a third resistor connected between an output end of the operational amplifier and the inversion input end, and an inductor connected between the non-inversion input end of the operational amplifier and a ground point; and
a fourth resistor having a resistance value sufficiently lower than respective resistance values of the first through third resistors connected between input and output terminals of the active all-pass type 90° phase advancing circuit and an impedance value of the inductor,
whereby an equivalent inductor is obtained between the input terminal and the ground point.
